(19) United States
(12) Patent Application Publication
(10) Pub. No.: US 2024/0120432 A1
(43) Pub. Date: Apr. 11, 2024

(54) METHOD FOR MANUFACTURING TRANSPARENT SOLAR CELL

(71) Applicant: ARCHE CO., LTD., Osan-si (KR)

(72) Inventors: Chan Uk JON, Cheonan-si (KR); Jun Yong BAK, Siheung-si (KR); Jae Kwang YOON, Hwaseong-si (KR)

(21) Appl. No.: 18/185,089

(22) Filed: Mar. 16, 2023

(30) Foreign Application Priority Data
Oct. 5, 2022 (KR) 10-2022-0127156

(51) Int. Cl. H01L 31/18; H01L 31/105

(52) U.S. Cl. CPC H01L 31/1804; H01L 31/105

(57) ABSTRACT

The present application relates to a method for manufacturing a transparent solar cell comprising a n-type semiconductor, a light absorption layer, and a p-type semiconductor including SiC.

### CROSS-REFERENCE TO RELATED APPLICATIONS

This application claims the priority of Korean Patent Application No. 10-2022-0127156 filed on Oct. 5, 2022, in the Korean Intellectual Property Office, the disclosure of which is incorporated herein by reference.

### BACKGROUND

### Field

The present application relates to a method for manufacturing a transparent solar cell.

### Description of the Related Art

Recently, as existing energy resources such as oil and coal are expected to be depleted, interest in alternative energy to replace them is increasing. Among them, solar cells are in the spotlight as next-generation batteries that convert solar energy into electrical energy.

A solar cell is a device that converts solar energy directly into electrical energy. A solar cell generates electricity using infinite solar energy and unlike other power generation systems, it is a quiet and safe eco-friendly system because it has no moving part.

In general, solar cells classify crystalline Si (polycrystalline and single crystalline) solar cells into I generation, compound semiconductor (III-V) and thin-film semiconductor (a-Si, CdTe, CIGS) solar cells into II generation, and organic and nano semiconductor materials into III generation.

Among them, a supply shortage of Si wafer is intensified in a crystalline Si solar battery, and there are problems of high costs caused by this supply imbalance, and additional cost reduction is not easy. In addition, thin-film solar cells have a problem that their energy conversion efficiency is much lower than that of crystalline Si solar cells. In order to commercialize a solar cell, a method of manufacturing a transparent solar cell having excellent productivity while improving the efficiency of the solar cell is required. Currently, solar cells using new materials are being developed, but there is a problem of low performance and manufacturing efficiency, and thus improvement of a manufacturing method of solar cells is required.

Korean Patent Application Publication No. 2008-0044183, which is the background technology of this application, relates to amorphous-crystalline tandem nanostructured solar cells.

### SUMMARY

The present application is to solve the aforementioned problems of the conventional art, and an object of the present application is to provide a transparent solar cell.

However, the technical tasks to be achieved by the example of the present application are not limited to the technical tasks as described above, and other technical tasks may exist.

As a technical means for achieving the above-mentioned technical tasks, a first aspect of the present application provides a transparent solar cell manufacturing method includes forming an n-type semiconductor on the lower substrate; forming a light absorption layer on the n-type semiconductor; forming a p-type semiconductor on the light absorption layer; and forming an upper substrate on the p-type semiconductor.

According to an embodiment of the present application, the n-type semiconductor, the light absorption layer, and the p-type semiconductor may each independently include those selected from the group consisting of Si, SiC, GaAs, CdTe, CdS, InP, and combinations thereof, but the present application is not limited thereto.

According to an embodiment of the present application, the n-type semiconductor, the light absorption layer, and the p-type semiconductor may include SiC, but the present application is not limited thereto.

According to an embodiment of the present application, a ratio of Si and C of the n-type semiconductor, a ratio of Si and C of the light absorption layer, and a ratio of Si and C of the p-type semiconductor may be different, but the present application is not limited thereto.

According to an embodiment of the present application, depending on the ratio of Si and C, wavelengths of light absorbed by the n-type semiconductor, the light absorption layer, and the p-type semiconductor may be different, but the present application is not limited thereto.

According to an embodiment of the present application, the step of forming the n-type semiconductor and the p-type semiconductor layer may include a step of forming amorphous SiC by independently applying plasma to a source and a dopant, and a step of annealing the amorphous SiC, but the present application is not limited thereto.

According to an embodiment of the present application, the source may include CH₄, and the dopant may include one selected from the group consisting of N₂, B₂H₆, trimethylamine (TMA), PH₃, and combinations thereof, but the present application is not limited thereto.

According to an embodiment of the present application, the forming of the light absorption layer may include forming amorphous SiC by applying plasma to a source, but the present application is not limited thereto.

According to an embodiment of the present application, the source may include CH₄, but the present application is not limited thereto.

According to an embodiment of the present application, the step of forming the n-type semiconductor, the step of forming the light absorption layer, and the step of forming the p-type semiconductor may be independently performed in an environment in which hydrogen, nitrogen, or oxygen gas is injected, but the present application is not limited thereto.

The above-described problem solving means are merely exemplary, and should not be construed as an intention of limiting the present application. In addition to the embodiments described above, additional embodiments may exist in the drawings and detailed description of the invention.

The method of manufacturing a transparent solar cell according to the present invention is to adjust the ratio of Si and C when manufacturing a SiC solar cell. In this regard, when the content of Si in the SiC solar cell is increased, the band gap of the solar cell is narrowed, and thus the J_{sc} performance may be improved, and when the content of C is increased, the band gap is widened and the V_{OC} performance may be improved.

Further, the manufacturing method of a transparent solar cell in accordance with this disclosure can reduce defects by adding hydrogen, nitrogen, or small gas when the contents of Si and C are controlled.

Further, in the solar cell according to this application, by arranging SiC having various compositions of Si and C in a multi-layer structure, sunlight can be efficiently absorbed in the multi-layer, hence improving the efficiency of the absorption layer.

However, the effects obtainable in the present application are not limited to the effects as described above, and another effect may exist.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 shows a schematic diagram of the method of manufacturing a transparent solar cell according to one Example of the present application.

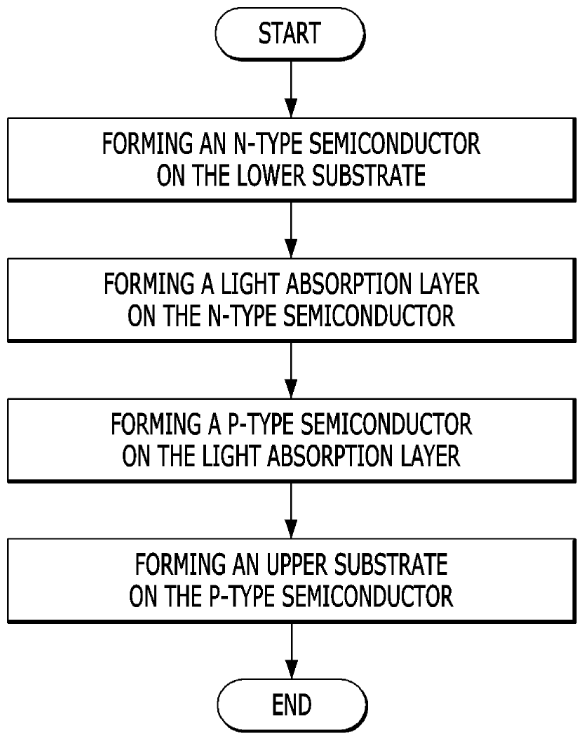

### DETAILED DESCRIPTION OF THE EMBODIMENT

Hereinafter, embodiments of the present application will be described in detail with reference to the accompanying drawings so that those with ordinary skill in the art to which the present application pertains will easily be able to implement the present application.

However, the present application may be implemented in various different forms and is not limited to the embodiments described herein. Further, parts irrelevant to the description are omitted in order to clearly describe the present application in the drawings, and similar reference numerals are attached to similar parts throughout the specification.

In the whole specification of the present application, when a part is said to be “connected” with other parts, it not only includes a case that the part is “directly connected” to the other parts, but also includes a case that the part is “electrically connected” to the other parts with another element being interposed therebetween.

In the whole specification of the present application, when any member is positioned “on”, “over”, “above”, “beneath”, “under”, and “below” other member, this not only includes a case that the any member is brought into contact with the other member, but also includes a case that another member exists between two members.

In the whole specification of the present application, if a prescribed part “includes” a prescribed element, this means that another element may be further included instead of excluding other elements unless any particularly opposite description exists.

When unique manufacture and material allowable errors of numerical values are suggested to mentioned meanings of terms of degrees used in the present specification such as “about”, “substantially”, etc., the terms of degrees are used in the numerical values or as a meaning near the numerical values, and the terms of degrees are used to prevent that an unscrupulous infringer unfairly uses a disclosure content in which exact or absolute numerical values are mentioned to help understanding of the present application. Further, in the whole specification of the present application, “a step to do ˜” or “a step of ˜” does not mean “a step for ˜”.

In the whole specification of the present application, a term of “a combination thereof” included in a Markush type expression, which means a mixture or combination of one or more selected from the group consisting of constituent elements described in the Markush type expression, means including one or more selected from the group consisting of the constituent elements.

In the whole specification of the present application, description of “A and/or B” means “A or B, or, A and B”.

Hereinafter, a method for manufacturing a transparent solar cell according to the present application will be described in detail with reference to embodiments, examples, and drawings. However, the present application is not limited to such embodiments, examples, and drawings.

As a technical means for achieving the above-mentioned technical tasks, the first aspect of the present application provides a transparent solar cell manufacturing method includes forming an n-type semiconductor on the lower substrate; forming a light absorption layer on the n-type semiconductor; forming a p-type semiconductor on the light absorption layer; and forming an upper substrate on the p-type semiconductor.

First, an n-type semiconductor is formed on the lower substrate.

Subsequently, a light absorption layer is formed on the n-type semiconductor. In this regard, the light absorption layer may be made of an intrinsic material, but is not limited thereto.

Subsequently, a p-type semiconductor is formed on the light absorption layer.

Subsequently, an upper substrate is formed on the p-type semiconductor.

According to an embodiment of the present application, the n-type semiconductor, the light absorption layer, and the p-type semiconductor may independently include, but are not limited to, SiC, GaAs, CdTe, CdS, InP, and combinations thereof.

According to an embodiment of the present application, the n-type semiconductor, the light absorption layer, and the p-type semiconductor may include SiC, but are not limited thereto.

According to an embodiment of the present application, a ratio of Si and C of the n-type semiconductor, a ratio of Si and C of the light-absorbing layer, and a ratio of Si and C of the p-type semiconductor may be different, but are not limited thereto.

In other words, the solar cell according to the present disclosure may include a structure in which n-type SiC, intrinsic SiC, and p-type SiC are disposed between the upper substrate and the lower substrate. In this regard, the intrinsic SiC refers to a light-absorbing layer, and the light-absorbing layer may include one or more intrinsic SiCs having different ratios of Si and C.

According to an embodiment of the present invention, the ratio of Si and C may be 1.8 to 2.2, but is not limited thereto.

According to an embodiment of the present application, wavelengths of light absorbed by the n-type semiconductor, the light absorption layer, and the p-type semiconductor may vary depending on the ratio of Si and C, but are not limited thereto.

The forming of the n-type semiconductor and the p-type semiconductor layer may include forming amorphous SiC by independently applying plasma to a source and a dopant, and annealing the amorphous SiC, but is not limited thereto.

According to an embodiment of the present disclosure, the source may include CH₄, and the dopant may include one selected from the group consisting of N₂, B₂H₆, trimethylamine (TMA), PH₃, and combinations thereof, but is not limited thereto.

When plasma is applied to the source, amorphous SiC may be formed. In this case, when plasma is applied on the dopant together with the source, a part of atoms or molecules constituting the dopant may be doped with the SiC to dope the amorphous SiC in an n-type or p-type.

Specifically, when the dopant is N₂ or B₂H₆, the amorphous SiC may be doped in an n type, and when the dopant is TMA or PH₃, the amorphous SiC may be doped in a p type. As will be described later, amorphous SiC formed without applying plasma to the dopant may function as a light absorption layer.

According to an embodiment of the present disclosure, the forming of the light absorbing layer may include forming amorphous SiC by applying plasma to a source, but is not limited thereto.

According to an embodiment of the present disclosure, the source may include CH₄, but is not limited thereto.

According to an embodiment of the present application, the step of forming the n-type semiconductor, the step of forming the light-absorbing layer, and the step of forming the p-type semiconductor may be independently performed in an environment in which hydrogen, nitrogen, or oxygen gas is injected, but are not limited thereto.

Hydrogen, nitrogen, and oxygen gas may be added to reduce defects that occur when the ratio of Si and C is adjusted in the process of forming the n-type semiconductor, p-type semiconductor, and the light absorption layer.

The foregoing description of the present application is for illustration, and those with ordinary skill in the art to which the present application pertains will be able to understand that it may be easily modified into other specific forms without changing the technical spirit or essential features of the present application. Therefore, it should be understood that the embodiments described above are illustrative in all respects and not restrictive. For example, each element described as a single form may be implemented in a dispersed form, and likewise elements described in the dispersed form may also be implemented in a combined form.

The scope of the present application is indicated by the claims to be described later rather than the above detailed description, and all changes or modified forms derived from the meaning and scope of the claims and equivalent concepts thereof should be construed as being included in the scope of the present application.

What is claimed is:

1. A method for manufacturing a transparent solar cell, the method comprising:
forming an n-type semiconductor on the lower substrate;
forming a light absorption layer on the n-type semiconductor;
forming a p-type semiconductor on the light absorption layer; and
forming an upper substrate on the p-type semiconductor.

2. The method of claim 1, wherein the n-type semiconductor, the light absorption layer, and the p-type semiconductor, each independently, include those selected from the group consisting of Si, SiC, GaAs, CdTe, CdS, InP, and combinations thereof.

3. The method of claim 2, wherein the n-type semiconductor, the light absorption layer, and the p-type semiconductor include SiC.

4. The method of claim 3, wherein the ratio of Si and C of the n-type semiconductor, the ratio of Si and C of the light absorption layer, and the ratio of Si and C of the p-type semiconductor are different.

5. The method of claim 4, wherein the wavelengths of light absorbed by the n-type semiconductor, the light absorption layer, and the p-type semiconductor are different according to the ratio of Si and C.

6. The method of claim 3, wherein the forming of the n-type semiconductor and the forming the p-type semiconductor layer independently includes forming amorphous SiC by applying plasma to a source and a dopant, and annealing the amorphous SiC.

7. The method of claim 6, wherein the source includes CH₄, and the dopant includes one selected from the group consisting of N₂, B₂H₆, trimethylamine (TMA), PH₃, and combinations thereof.

8. The method of claim 3, wherein the forming of the light absorption layer includes forming amorphous SiC by applying plasma to a source.

9. The method of claim 8, wherein the source includes CH 4.

10. The method of claim 1, wherein the step of forming the n-type semiconductor, the step of forming the light absorption layer, and the step of forming the p-type semiconductor are each independently performed in an environment in which hydrogen, nitrogen, or oxygen gas is injected.
